(19) United States
(12) Patent Application Publication
(10) Pub. No.: US 2023/0070727 A1
(43) Pub. Date: Mar. 9, 2023

(54) OPTOELECTRONIC COMPONENT, AND METHOD OF VARYING THE CONTRAST BETWEEN EMITTERS

(71) Applicant: ams-OSRAM International GmbH, Regensburg (DE)

(72) Inventors: Moritz Laubscher, Göllheim (DE); Dominik Eisert, Regensburg (DE)

(21) Appl. No.: 17/800,146

(22) PCT Filed: Feb. 9, 2021
(86) PCT No.: PCT/EP2021/053092

§ 371 Date: Aug. 16, 2022

(30) Foreign Application Priority Data
Feb. 21, 2020 (DE) 10 2020 104 670.7

(51) Int. Cl. H01L 33/58; H01L 33/50; H05B 3/34

(52) U.S. Cl. CPC H01L 33/58; H01L 33/50; H05B 3/34

(57) ABSTRACT

An optoelectronic component includes a semiconductor chip with a plurality of emitters that emit a primary radiation in a main radiation direction in a first state and do not emit primary radiation in a second state, and an absorber arranged subsequent to the emitters in the main radiation direction, wherein the absorber includes a lower absorption coefficient in first regions associated with emitters in the first state than in second regions associated with emitters in the second state, a conversion layer arranged in the main radiation direction on at least one emitter of the semiconductor chip, and 1) the absorber is present in particle form embedded in the conversion layer, or 2) the absorber is present in an absorber layer, wherein the absorber layer is arranged in the main radiation direction on a side of the conversion layer facing away from the chip, and the absorber layer is electrically contacted.

### TECHNICAL FIELD

This disclosure relates to an optoelectronic component comprising an increased contrast between emitters of the component and a method of contrast enhancement as well as a method of varying the contrast between emitters of an optical component.

### SUMMARY

We provide an optoelectronic component including a semiconductor chip with a plurality of emitters configured independently of one another to emit a primary radiation in a main radiation direction in a first operating state and not to emit primary radiation in a second operating state, and an absorber arranged subsequent to the emitters in the main radiation direction, wherein the absorber includes a lower absorption coefficient in first regions associated with emitters in the first operating state than in second regions associated with emitters in the second operating state, a conversion layer is arranged in the main radiation direction on at least one emitter of the semiconductor chip, and 1) the absorber is present in particle form embedded in the conversion layer, or 2) the absorber is present in an absorber layer, wherein the absorber layer is arranged in the main radiation direction on a side of the conversion layer facing away from the semiconductor chip, and the absorber layer is electrically contacted.

We also provide a method of contrast enhancement between emitters of an optoelectronic component, wherein the optoelectronic component includes a semiconductor chip with a plurality of emitters independently of one another configured to emit a primary radiation in a main radiation direction in a first operating state and not to emit primary radiation in a second operating state, and an absorber arranged subsequent to the emitters in the main radiation direction, wherein the absorber includes a lower absorption coefficient in first regions associated with emitters in the first operating state than in second regions associated with emitters in the second operating state, the method including heating the absorber to a temperature above the glass transition temperature, cooling the absorber in the first regions to a temperature below the glass transition temperature in a time t₁, and cooling the absorber in the second regions to a temperature below the glass transition temperature in a time t₂, wherein t₁<t₂.

We further provide a method of varying a contrast between emitters of an optoelectronic component, wherein the optoelectronic component includes a semiconductor chip with a plurality of emitters independently of one another configured to emit a primary radiation in a main radiation direction in a first operating state and not to emit primary radiation in a second operating state, and an absorber arranged subsequent to the emitters in the main radiation direction, wherein the absorber includes a lower absorption coefficient in first regions associated with emitters in the first operating state than in second regions associated with emitters in the second operating state, the method including heating the absorber on at least one emitter to a temperature above the crystallization temperature, and cooling the absorber on the at least one emitter to a temperature below the crystallization temperature, wherein the absorption coefficient of the absorber on the at least one emitter after cooling is changed with respect to the absorption coefficient before heating.

### BRIEF DESCRIPTION OF THE DRAWINGS

FIGS. 1 to 7 each show a schematic sectional view of an optoelectronic component according to various examples.

FIG. 8 shows a rough estimate of the relative contrast gain over the relative brightness loss.

### REFERENCE LIST

1 optoelectronic component
2 semiconductor chip
3 emitter
4 first operating state
5 second operating state
6 absorber
7 first region
8 second region
9 conversion layer
10 absorber layer
U voltage

### DETAILED DESCRIPTION

The optoelectronic component is a radiation-emitting optoelectronic component.

The optoelectronic component may comprise a semiconductor chip with a plurality of emitters. In particular, the semiconductor chip is a monolithic light emitting diode (LED) structured into a plurality of emitters. A structured light emitting diode may also be referred to as a pixelated LED. For example, the semiconductor chip is a monolithic InGaN LED, a monolithic InGaAlP LED, a monolithic InGaAs LED, or a monolithic GaInNAs LED. The semiconductor chip comprises at least two emitters, in particular at least 10 emitters, preferably at least 100 emitters, for example, 1024 emitters or 25400 emitters.

The emitters may be independent of one another and configured to emit a primary radiation in a main radiation direction in a first operating state and not to emit primary radiation in a second operating state. Here and hereinafter, “none” with respect to emission of primary radiation shall also be understood to include emission of primary radiation that is “only negligible” or “imperceptible to an outside observer.” In other words, an emitter is active in the first operating state and an emitter is inactive in the second operating state. During operation of the optoelectronic component, the operating state of one emitter may be changed independently of the operating states of the other emitters, for example, in dependence of an applied voltage. For example, it is possible to switch an emitter between the first operating state and the second operating state independently of the other emitters of the semiconductor chip. In particular, the emitters may comprise further operating states.

The primary radiation is electromagnetic radiation of a first wavelength range. In particular, each emitter may emit primary radiation of a first wavelength range independently of the further emitters. For example, each emitter emits, independently of the further emitters, a primary radiation in the blue wavelength range, for example, in the region from 400 nm to 500 nm, or in the red wavelength range, for example, in the region from 580 nm to 650 nm.

The optoelectronic component may comprise an absorber arranged subsequent to the emitters in the main radiation direction. In other words, the absorber is arranged on a radiation exit surface of the semiconductor chip. An absorber is a material that comprises an absorption coefficient. The absorber is configured to at least partially or completely absorb incident electromagnetic radiation depending on its absorption coefficient. In particular, the absorber comprises a broadband absorption. Thus, the absorber may be configured to absorb electromagnetic radiation from the blue to the red wavelength range, inclusive.

The absorber may comprise a lower absorption coefficient in first regions associated with emitters in the first operating state than in second regions associated with emitters in the second operating state. Thus, the first regions may be associated with active emitters and the second regions may be associated with inactive emitters. The first regions may also be referred to as active regions and the second regions may be referred to as inactive regions. Accordingly, electromagnetic radiation with a high intensity is coupled out of the first regions, whereas no electromagnetic radiation or electromagnetic radiation with a low intensity is coupled out of the second regions. In particular, electromagnetic radiation with a low intensity can be coupled out from the second regions, which is generated by the emitters in the first operating state and is scattered from the first regions into the second regions.

Regions associated with emitters do not necessarily include the net area of the emitters. Regions may also comprise adjacent areas in which the effect of the emitter's operating state can be observed. Similarly, regions may be smaller than the net area of the emitters. For example, a first region associated with an emitter in the first operating state may also comprise adjacent sub-areas of adjacent emitters in the second operating state upon which scattered radiation from the emitter in the first operating state impinges. For the same reason, a second region associated with an emitter in the second operating state may have a smaller area associated therewith. In particular, the first regions are larger than the net area of the associated emitters and the second regions are smaller than the net area of the associated emitters.

The absorber comprises a lower absorption coefficient in first regions than in second regions. Thus, radiation is absorbed less in first regions than in second regions. First regions, i.e. regions with high intensity, experience a low attenuation, whereas second regions with low intensity are attenuated more strongly. This can increase the contrast between active and inactive emitters.

The optoelectronic component may comprise a semiconductor chip with a plurality of emitters that are independently of one another configured to emit a primary radiation in a main radiation direction in a first operating state and not to emit primary radiation in a second operating state, and an absorber arranged subsequent to the emitters in the main radiation direction, wherein the absorber comprises a lower absorption coefficient in first regions associated with emitters in the first operating state than in second regions associated with emitters in the second operating state.

The optoelectronic component is based on the following considerations, inter alia: For pixelated LEDs, contrast is an important product property. The exact definition of contrast varies depending on the application and the product, in general, contrast is defined as the ratio between “luminance of an active region” and “luminance of an inactive region”. By having an absorber that comprises a lower absorption coefficient in first regions than in second regions, regions with a high intensity will experience a low attenuation, whereas regions with a low intensity will be attenuated more strongly. Thus, the contrast between the individual emitters can be significantly increased. The absorber can thereby lead to a separation or decoupling of the emitters.

In particular, good channel separation of small emitters can be achieved in a monolithic LED without a grating. When a grating is used, light incident on the grating is either absorbed or reflected, which in conjunction with the other components of the component leads to a significant loss of efficiency. Since a grating acts primarily at the emitter edges, the edge-to-area ratio plays a major role. When using discrete LEDs, channel separation of the individual emitters can also be created in principle, but here the emitter size and emitter spacing is limited downwards to structure sizes of 50-100 μm by the package design and backend processes during manufacturing.

Advantageously, a contrast improvement in the order of 20% to 40% can be achieved independently of the emitter size and only depending on the concentration of the absorber or the layer thickness of an absorber layer. In addition, compatibility with existing back-end processes is advantageous. The absorber allows contrast to be adjusted at the expense of component brightness of the component, which is an advantage in process control or fabrication, and which can circumvent contrast binning. In addition, it may be advantageous to control component brightness without additional effort or cost. For example, it may be necessary to substantially dim a component designed for very high brightness such as in front headlights, for indoor use without greatly changing the current-voltage characteristics.

Advantageously, the contrast of the component can also be adjusted after the component has been manufactured, for example, while the component is in operation. Thus, the contrast between individual emitters of the component can be adjusted in dependence of the operating state of the emitter such that the contrast between active and inactive emitters is increased.

The absorber may be a saturable absorber. A saturable absorber may be a passive optical switching element. A saturable absorber is characterized in that its absorption coefficient is intensity dependent. In particular, the material of a saturable absorber becomes transparent to electromagnetic radiation when a threshold level of photons is reached. Saturable absorbers whose threshold value has been reached remain transparent to electromagnetic radiation at least as long as the threshold value of photons is exceeded. If the photon threshold value is undercut, the absorption of the saturable absorbers increases again after a relaxation time. The saturable absorbers then become nontransmissive or less transmissive to electromagnetic radiation again.

An absorption coefficient of the saturable absorber may decrease with increasing intensity of an electromagnetic radiation. The electromagnetic radiation may be the primary radiation of the semiconductor chip or a secondary radiation that is at least partially different from the primary radiation of the semiconductor chip. The secondary radiation may be wavelength-converted primary radiation generated, for example, by a conversion agent such as a phosphor arranged in the optoelectronic component. The absorption coefficient of the saturable absorber thereby decreases with the excitation intensity of the electromagnetic radiation. In other words, a saturable absorber absorbs less the more intense the incident electromagnetic radiation, i.e., the higher the photon count. Photons in a first region associated with active emitters are therefore less likely to be absorbed than photons in a second region associated with inactive emitters. This behavior results in contrast improvement between the first and second regions.

The saturable absorber may be a graphene or a semiconductor material such as GeSbTe, GaN or InGaN. The saturable absorber may be selected from the group consisting of graphene, GeSbTe, GaN, InGaN, and combinations thereof.

The absorber may be a phase change material. A phase change material (PCM) is characterized by a crystallization temperature and/or glass transition temperature in the region of 100° C. to 300° C., in particular in the region of 100° C. to 200° C., preferably of 150° C. In particular, a phase change material comprises both a crystallization temperature and a glass transition temperature in the region of 100° C. to 300° C., especially in the region of 100° C. to 200° C., preferably of 150° C. The crystallization temperature can be adjusted via the composition of the phase change material, in particular a ternary compound. A phase change material comprises a very fast phase transition in the region of nanoseconds and/or a material phase-dependent dielectric function. For example, germanium antimony tellurium compounds can be used as phase change materials. When using a phase change material as an absorber, it can be configured that a different phase is present in first regions than in second regions. As a result, a contrast improvement of up to 200% between the first and second regions is possible in the visible light region.

The phase change material may comprise a reversible phase transition from a crystalline phase to an amorphous phase. In this example, the phase change material is present in both the crystalline phase and the amorphous phase in the solid state, i.e., as a solid. A crystalline phase means that the material of the absorber consists of crystallized, regularly structured material and has both a near order and a far order. An amorphous phase means that the material of the absorber does not comprise an ordered structure, but forms an irregular pattern and has only a near order, but not a far order. In particular, the crystalline phase and the amorphous phase can exist side by side during operation of the optoelectronic component. Thus, the phase change material may be present in both the crystalline phase and the amorphous phase at the operating temperature of the optoelectronic component.

The phase transition between the crystalline and the amorphous phase takes place in particular by exceeding the glass transition temperature of the phase change material. In this process, the phase change material enters a melt above the glass transition temperature, from which the phase change material can transition to the crystalline phase or the amorphous phase. For example, the transition to the amorphous phase can take place via rapid cooling and the transition to the crystalline phase via slow cooling.

The phase transition may be controlled thermally, in particular optically and/or electrically. The phase transition takes place by exceeding the glass transition temperature and subsequent cooling. Exceeding the glass transition temperature can be achieved by heating the phase change material. Heating to a temperature above the glass transition temperature can take place in the nanosecond range. For example, the phase change material is heated via the luminous intensity of the primary radiation or the application of a voltage. For electrical switching of a phase-change material, the material must be contacted in an electrically conductive manner, in particular. The cooling of the phase change material can then be initiated via the reduction of the luminous intensity or the switching off of the voltage. For example, the emitters associated with the first regions are turned off or operated with a low luminous intensity to achieve rapid cooling, while the emitters associated with the second regions are operated with a higher luminous intensity to achieve slow cooling, during which crystallization nuclei can form.

It is also possible to control the phase transition by a combination of luminous intensity and current feed. For example, exceeding the glass transition temperature occurs electrically and the transition to the crystalline or amorphous phase occurs optically.

The absorption coefficient of the phase change material may be dependent on the phase of the phase change material. Phase change materials are so-called switchable absorbers. In particular, the absorption of the phase change material at the power densities generated during operation of LEDs is independent of the power density of the electromagnetic radiation, and only dependent on the phase structure of the respective phase of the phase change material. As a result, during operation of the optoelectronic component, uniform absorption of electromagnetic radiation can be achieved independently of its power density.

The crystalline phase may comprise a higher absorption coefficient than the amorphous phase. In the optoelectronic component, the crystalline phase of the absorber may be arranged on the second regions and the amorphous phase of the absorber may be arranged on the first regions. The higher absorption coefficient of the absorber in the crystalline phase on the second regions results in increased absorption of electronic radiation there compared to the absorber in the amorphous phase on the first regions. The photons that would be coupled out through the second region are absorbed more by the crystalline state of the absorber than the photons that are coupled out through the first region. This can advantageously improve the contrast between the emitters in the first operating state and the emitters in the second operating state.

An absorption coefficient of the crystalline phase may be higher than an absorption coefficient of the amorphous phase by a factor of 2. As a result, the absorber in the crystalline phase comprises an absorption twice as large as that of the absorber in the amorphous phase, which can advantageously significantly improve the contrast between emitters in the first operating state and emitters in the second operating state.

The phase change material may be selected from the group consisting of GeTe, GeSbTe, Ge₂Sb₂Te₅, GeSb₂Te₄, GeSb₄Te₇, Sb₂Te₃, VO₂, V₂O₅, AgInTe₂, InSb, and combinations thereof. These compounds have crystallization temperatures in the region of 100° C. to 300° C., a very fast phase transition in the region of nanoseconds, and a material-dependent dielectric function. These compounds are class 2 absorbers, the class of phase change materials, in particular the subclasses of phase change materials that change absorption. With these materials, contrast improvement in the order of 20% to 40% can be achieved regardless of the emitter size and only depending on the concentration of the absorber or the thickness of an absorber layer. This makes them particularly suitable for use as absorbers in an optoelectronic component.

A conversion layer may be arranged in the main radiation direction on at least one emitter of the semiconductor chip. In particular, the conversion layer may be arranged on all emitters of the semiconductor chip. Alternatively, the conversion layer may be arranged on only a part of the emitters. In particular, the further emitters on which the conversion layer is not arranged may be free of a conversion layer. Alternatively or additionally, a further conversion layer may be arranged on the further emitters or on a part of the further emitters.

In particular, the conversion layer comprises a thickness of 3 μm to 150 μm, in particular 100 μm to 130 μm, for example, 120 μm.

The conversion layer comprises at least one phosphor. In particular, the phosphor in the conversion layer is present as a ceramic or in a matrix material. A phosphor present as a ceramic is in particular largely free of a matrix material and/or a further phosphor. Alternatively, the phosphor is embedded in a matrix material, in particular in particle form. The matrix material comprises, for example, silicone or glasses.

The phosphor in the conversion layer can completely or at least partially convert the primary radiation of the semiconductor chip into electronic radiation of a second wavelength range, the secondary radiation. The conversion of primary radiation into secondary radiation is also referred to as wavelength conversion. In particular, the secondary radiation comprises a wavelength range that is at least partially different from the primary radiation. For example, the phosphor converts blue primary radiation into yellow secondary radiation.

The conversion layer may comprise a filler. The filler is present in particle form with particle sizes of 1 μm to 20 μm. The filler comprises, for example, TiO₂, SiO₂ or ZrO₂. The filler has the function of scattering electromagnetic radiation, in particular primary and/or secondary radiation.

The absorber may be present in particle form embedded in the conversion layer. The absorber is integrated into the conversion layer. For this purpose, the conversion layer comprises, in particular, a matrix material. The absorber may then be embedded in the matrix material in the same way as the phosphor in particle form. The absorber may be applied to the emitters by embedding the absorber in particle form in the conversion layer in the same manufacturing step as the application of the conversion layer, allowing existing processes to be used.

A concentration of the absorber in the conversion layer may be between 0 wt % (weight percent) and 15 wt %, in particular between 5 wt % and 10 wt %, for example, 7 wt %. Since phase change materials in particular comprise a very strong absorption, only a relatively small amount of absorber is required in the conversion layer to achieve sufficient absorption for contrast enhancement.

The absorber may be present in an absorber layer. The absorber layer is present alternatively or in addition to the conversion layer. The absorber may be present in the absorber layer in particle form in a matrix material or may be produced as a homogeneous layer consisting of the absorber material, for example, by vapor deposition or sputtering. The matrix material for the absorber layer comprises, for example, the above-mentioned matrix materials for the conversion layer.

The absorber layer may be arranged on the semiconductor chip in the main radiation direction. In particular, no conversion layer is arranged between the absorber layer and the semiconductor chip. For example, the absorber layer is applied to the radiation exit surface of the semiconductor chip in direct mechanical contact. In particular, the electronic component in this example does not comprise a conversion layer. Such a configuration of the optoelectronic component enables contrast improvement between the emitters of a monolithic pixelated LED or a pixelated semiconductor chip during emission of primary radiation.

The absorber layer may be arranged in the main radiation direction on a side of the conversion layer facing away from the semiconductor chip. The absorber layer can be arranged in direct mechanical contact on the conversion layer. Alternatively, further layers, for example, adhesive layers may be arranged between the conversion layer and the absorber layer. In particular, the conversion layer is free of an absorber. Such a configuration of the optoelectronic component enables contrast improvement between the emitters when emitting secondary radiation or white light.

The absorber layer may be electrically contacted. For example, the absorber layer is electrically contacted from the component side. By electrically contacting the absorber layer, a voltage can be applied to the absorber layer, enabling, for example, electrical switching of an absorber comprising a phase change material.

The absorber layer may comprise a thickness of 10 μm to 40 μm, in particular 10 μm to 30 μm, for example, 20 μm. The thickness of the absorber layer, in particular of a homogeneous absorber layer, may have an influence on the absorption of electromagnetic radiation. In particular, the absorption increases with increasing thickness of the absorber layer. On the one hand, this can reduce the component brightness, but on the other hand, it can also improve the contrast between the individual emitters.

The absorber may be present in particle form and comprises a particle size of 1 μm to 20 μm. The particle size may comprise a certain distribution. Due to these particle sizes, the absorber may also be suitable for scattering electromagnetic radiation, in particular primary and/or secondary radiation.

We also provide a method of contrast enhancement between emitters of an optoelectronic component. Preferably, the method is suitable and provided for use in an optoelectronic component described above. Features or structures described in connection with the optoelectronic component also apply to the method and vice versa.

The method of contrast enhancement between emitters of an optoelectronic component, wherein the optoelectronic component comprises a semiconductor chip with a plurality of emitters that are independently of one another configured to emit a primary radiation in a main radiation direction in a first operating state and not to emit primary radiation in a second operating state and an absorber arranged subsequent to the emitters in the main radiation direction, wherein the absorber comprises a lower absorption coefficient in first regions associated with emitters in the first operating state than in second regions associated with emitters in the second operating state, the method may comprise:

heating the absorber to a temperature above the glass transition temperature,
cooling the absorber in the first regions to a temperature below the glass transition temperature in a time t₁, and
cooling the absorber in the second regions to a temperature below the glass transition temperature in a time t₂, wherein t₁<t₂.

Heating the absorber to a temperature above the glass transition temperature occurs in particular in the region of nanoseconds. Above the glass transition temperature, the absorber is present in a melt.

In particular, the structure of the absorber is affected by the rate of cooling. For example, the time t₁ is in the region of nanoseconds and the time t₂ is in the region of microseconds. Thus, the absorber cools faster in the first regions than in the second regions. Due to the faster cooling in time t₁, the absorber in the first regions transitions into the amorphous phase. Due to the slower cooling in time t₂, the absorber in the second regions transitions into the crystalline phase. The times t₁ and t₂ are strongly dependent on the material used. For example, for germanium antimony telluride compounds, especially for GeSbTe, a time t₁ smaller than 50 ns and for t₂ of about 0.2 μs is used. Thus, the absorber comprises a lower absorption coefficient in the first regions than in the second regions.

With such a method, the contrast between the emitters of the optoelectronic component can be adjusted during production or after completion of the component. In particular, the method is reversible, whereby the contrast can be flexibly and variably adjusted according to various requirements.

The absorber may be a phase change material. Phase change materials are particularly advantageously suited for the method since they comprise very fast phase transitions in the region of nanoseconds, material phase-dependent dielectric functions and crystallization temperatures in the region of 100° C. to 300° C. By using a phase change material, a contrast improvement of up to 200% can be achieved in the region of visible light with the method described here.

Heating of the absorber to a temperature above the glass transition temperature may be performed electrically. For this purpose, a voltage can be applied to the absorber material, in particular to the layer containing the absorber. In particular, the applied voltage is so high that the absorber is heated to a temperature above the glass transition temperature on all emitters.

Heating of the absorber to a temperature above the glass transition temperature may be performed optically. The primary radiation of the individual emitters can be used for this purpose. Heating takes place via the luminous intensity of the primary radiation. The luminous intensity is thereby above the luminous intensity of the emitters in the first operating state of the emitters of the optoelectronic component. In particular, all emitters are operated with such a high luminous intensity that the absorber on all emitters is heated to a temperature above the glass transition temperature.

Heating the absorber to a temperature above the glass transition temperature may be performed electrically and cooling the absorber to the first and second regions is performed optically. Accordingly, the phase transition is controlled by a combination of luminous intensity and current feed.

We further provide a method of varying a contrast between emitters of an optoelectronic component. Preferably, the method is suitable and provided for use in an optoelectronic component described above. Features or structures described in connection with the optoelectronic component or the method of contrast enhancement between emitters of an optoelectronic component also apply to the method of varying a contrast between emitters of an optoelectronic component, and vice versa. The method of varying a contrast may also be an additional method step in the method of contrast enhancement.

The method of varying a contrast between emitters (3) of an optoelectronic component (1), wherein the optoelectronic component (1) comprises a semiconductor chip (2) with a plurality of emitters (3) that are independently of one another configured to emit a primary radiation in a main radiation direction in a first operating state (4) and not to emit primary radiation in a second operating state (5), and an absorber (6) arranged subsequent to the emitters (3) in the main radiation direction, wherein

the absorber (6) comprises a lower absorption coefficient in first regions (7) associated with emitters (3) in the first operating state (4) than in second regions (8) associated with emitters (3) in the second operating state (5),
the method may comprise:
heating the absorber (6) on at least one emitter (3) to a temperature above the crystallization temperature, and
cooling the absorber (6) on the at least one emitter (3) to a temperature below the crystallization temperature, wherein the absorption coefficient of the absorber (6) on the at least one emitter (3) after cooling is changed with respect to the absorption coefficient before heating.

The absorber on one emitter is the absorber arranged subsequent to the emitter.

For example, the absorption coefficient of the absorber on the at least one emitter before heating is the same as the absorption coefficient of the absorber in the second regions. Then, after heating and cooling, the absorption coefficient may be equal to the absorption coefficient of the absorber in the first regions. Alternatively, before heating, the absorption coefficient of the absorber on the at least one emitter may correspond to the absorption coefficient of the absorber in the first regions, and then after heating and cooling, the absorption coefficient may correspond to the absorption coefficient of the absorber in the second regions. In particular, the absorption coefficient of a specific emitter can be selectively adjusted when the assignment of an emitter to the first or second operating condition changes.

With such a method, the contrast between individual emitters of the optoelectronic component can be changed, in particular increased, during production or after completion of the component. In particular, with such a method, the absorption coefficient of a specific absorber can be selectively changed without changing the absorption coefficients of the absorbers on the further emitters.

The absorption coefficient of the absorber may be adjusted by the rate of cooling. For example, cooling in time t₁ is in the region of nanoseconds or in time t₂ is in the region of microseconds. The faster cooling in time t₁ causes the absorber to transition into the amorphous phase. Due to the slower cooling in time t₂, the absorber transitions into the crystalline phase. The times t₁ and t₂ are strongly dependent on the material used. For example, for germanium antimony telluride compounds, in particular GeSbTe, a time t₁ of less than 50 ns and for t₂ of about 0.2 μs is used.

The absorber may be a phase change material. Phase change materials are particularly advantageously suited for the method described here since their absorption coefficients depend on the respective phase and can thus be adjusted and thus changed by changing the phase.

The heating of the absorber on at least one emitter to a temperature above the crystallization temperature may be carried out optically. For this purpose, the luminous intensity of the primary radiation of the emitter can be used. The luminous intensity is thereby above the luminous intensity of an emitter in the first operating state of the optoelectronic component. In particular, the luminous intensity of the emitter is adjusted to heat the absorber to a temperature above the crystallization temperature, but not the glass transition temperature. In particular, the heating of the absorber to a temperature above the crystallization temperature takes place in the region of nanoseconds.

Further advantages, configurations and further developments of the optoelectronic component and the method of contrast enhancement between emitter as optoelectronic component result from the following examples shown in connection with the figures.

Elements that are the same, similar, or have the same effect are indicated in the figures with the same reference signs. The figures and the size ratios of the elements shown in the figures to one another are not to be regarded as to scale. Rather, individual elements, in particular layer thicknesses, may be shown exaggeratedly large for better illustration and/or understanding.

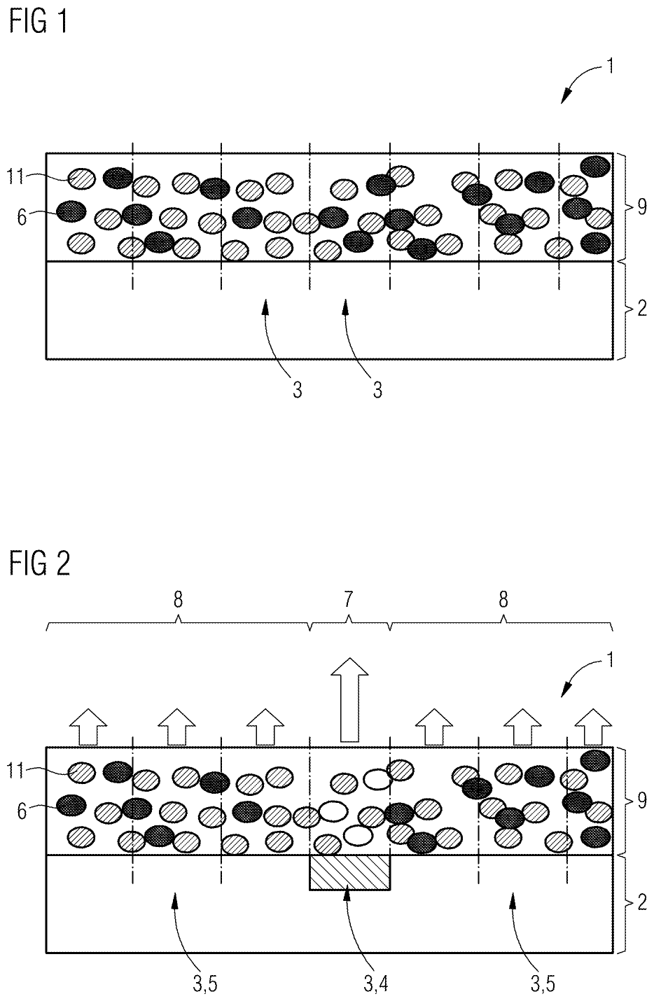

FIGS. 1 and 2 each show an optoelectronic component 1 according to an example. The optoelectronic component 1 comprises a semiconductor chip 2 which comprises a plurality of emitters 3. Pixelation of the semiconductor chip 2 is illustrated by vertical dashed lines. The emitters 3 of the semiconductor chip 2 are independently of one another configured to emit a primary radiation during operation of the optoelectronic component 1. For example, each emitter 3 may emit a primary radiation in the blue or red wavelength range.

Each emitter 3 comprises at least two operating states that can be set independently of the operating states of the other emitters during operation of the optoelectronic component 1 (FIG. 2). The emitters 3 may comprise a first operating state 4 (shown hatched) in which they emit primary radiation in a main radiation direction. Emitters 3 in the first operating state 4 may also be referred to as active emitters. Emitters 3 may comprise a second operating state 5 in which they do not emit primary radiation or emit primary radiation that is not perceptible to an external observer. Emitters 3 in the second operating state 5 may also be referred to as inactive emitters.

A conversion layer 9 is arranged on the emitters 3 of the semiconductor chip 2 in the main radiation direction. The conversion layer 9 comprises a phosphor 11. The phosphor 11 is present in the conversion element 9 in particle form. The phosphor 11 may be embedded in a matrix material of, for example, silicone. The phosphor 11 is configured to partially or completely convert the primary radiation emitted by the emitters 3 into secondary radiation.

According to the example of FIGS. 1 and 2, the conversion layer 9 further comprises an absorber 6. The absorber 6 is present in the conversion element 9 in particle form. The absorber 6 is embedded in the matrix material. The absorber comprises a concentration in the conversion layer of 0 wt % to 15 wt %, for example, 10 wt %.

The absorber 6 is a saturable absorber or a phase change material. In either example, the absorber 6 comprises a lower absorption coefficient in first regions 7 associated with emitters 3 in the second operating state 4 than in second regions 8 associated with emitters 3 in the second operating state 5. In particular, the absorber 6 comprises a lower absorption coefficient in first regions 7 for both primary radiation and secondary radiation.

The effect of the absorber 6 is illustrated in FIG. 2. Due to its lower absorption coefficient, the absorber 6 in the first region 7 is more permeable to electromagnetic radiation than the absorber 6 in second regions 8. The absorber 6 with a lower absorption coefficient is shown with a white filling. Due to the lower absorption coefficient of the absorber 6, the electromagnetic radiation in the first regions 7 is absorbed less than the electromagnetic radiation reaching the absorber 6, for example, as scattered radiation in the second regions 8. As a result of the electromagnetic radiation in the first active regions 7 being absorbed less strongly than electromagnetic radiation in regions of the inactive second regions 8, the contrast between the active first regions 7 and the inactive second regions 8 is improved and decoupling or separation of the individual emitters 3 in the different operating states 4,5 is achieved.

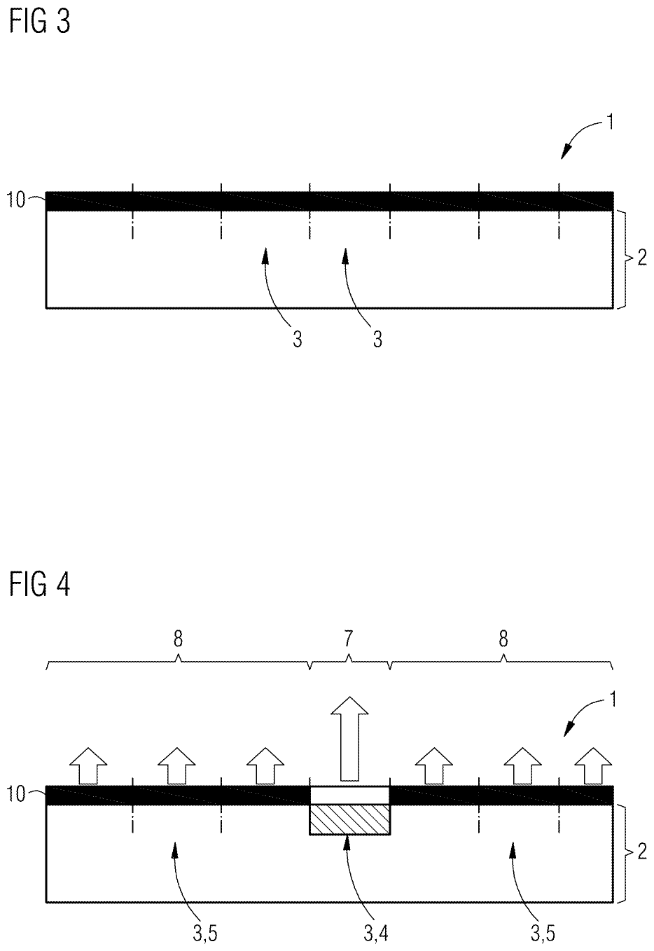

FIGS. 3 and 4 show an optoelectronic component 1 according to a further example. The optoelectronic component comprises the same semiconductor chip 2 of the example of FIGS. 1 and 2. In contrast to the optoelectronic component 1 of FIGS. 1 and 2, the optoelectronic component 1 of FIGS. 3 and 4 does not comprise a conversion layer. An absorber layer 10 is arranged on the emitters 3 of the semiconductor chip 2 in the main radiation direction, in particular in direct mechanical contact.

The absorber layer 10 comprises a saturable absorber or a phase change material. The saturable absorber or the phase change material may be embedded in a matrix material, for example, of silicone. Alternatively, the absorber layer 10 may consist of the saturable absorber or the phase change material. For example, the absorber material can be homogeneously vapor deposited for this purpose. The absorber layer 10 comprises a thickness of 10 μm to 40 μm, for example, 20 μm. Thus, the absorber can be applied as a thin layer to the emitters 3 of the semiconductor chip 2.

The effect of the absorber layer 10 is illustrated in FIG. 4. The absorption coefficient of the absorber layer 10 is lower in the first regions 7 than in the second regions 8. Thus, the electromagnetic radiation emitted from an emitter 3 in the first operating state 4 is absorbed to a lesser extent than the electromagnetic radiation reaching the absorber layer 10 in the second regions 8. By the electromagnetic radiation of the active emitters 4 being absorbed less than electromagnetic radiation in regions of the inactive emitters 5, for example, scattered radiation, the contrast between the active emitters 4 and inactive emitters 5 is improved.

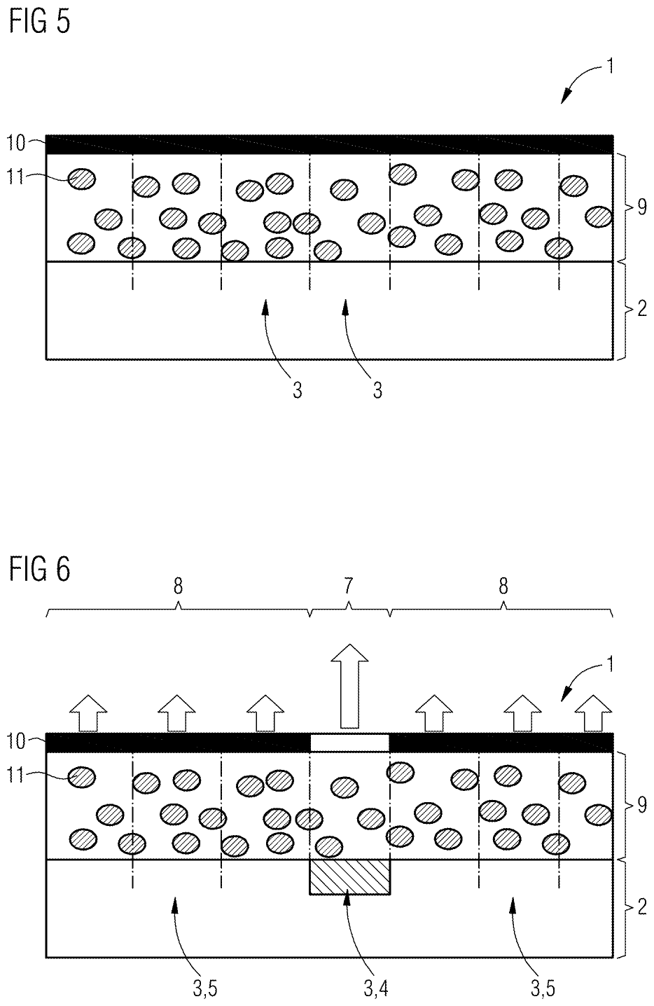

FIGS. 5 and 6 show an optoelectronic component 1 according to a further example. In contrast to the examples of FIGS. 1 and 3, the optoelectronic component 1 in FIGS. 5 and 6 comprises a conversion layer 9 and an absorber layer 10 arranged in the main radiation direction on the emitters 3 of the semiconductor chip 2. In particular, the absorber layer 10 is arranged in the main radiation direction on a side of the conversion layer 9 facing away from the semiconductor chip 2.

The conversion layer 9 comprises a phosphor 11. The phosphor 11 is embedded in a matrix material. In particular, the conversion element may additionally comprise a filler configured to scatter the primary radiation and/or the secondary radiation. Alternatively, the conversion layer 9 may comprise a ceramic of the phosphor 11 (not shown here). In particular, the conversion layer 9 may be free of an absorber.

The absorber layer 10 comprises the same properties as the absorber layer of the example of FIGS. 3 and 4. In particular, the absorber layer 10 comprises a lower absorption coefficient in first regions 7 for both the primary radiation and the secondary radiation.

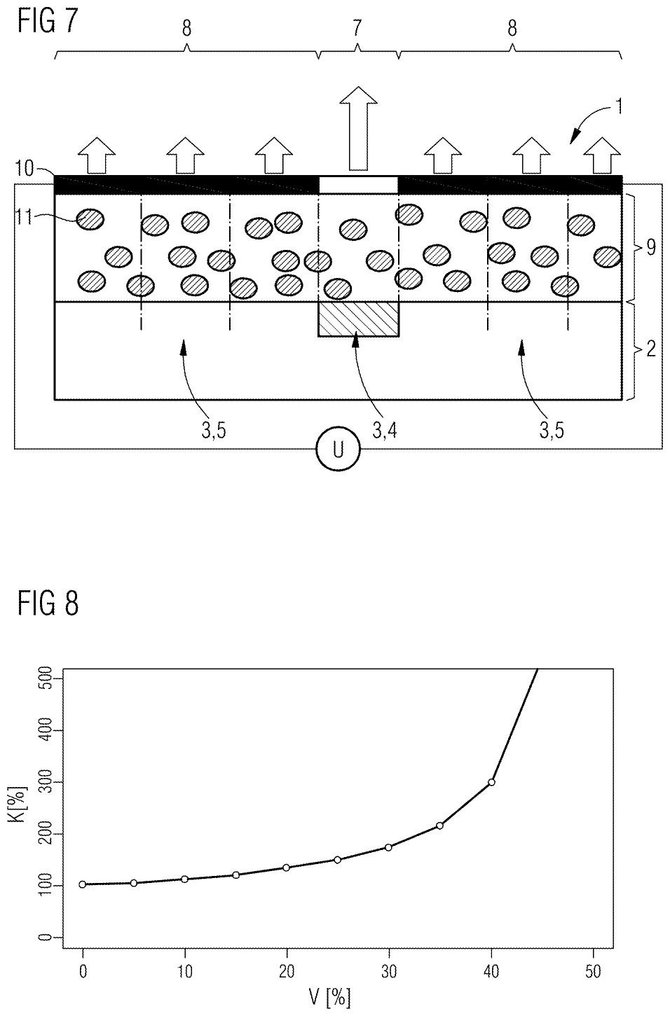

FIG. 7 shows the optoelectronic component 1 of FIG. 5, in which the absorber layer 10 is additionally electrically conductively contacted. For example, the absorber layer can be contacted from the component side (here illustrated by the symbol U for the applied voltage). In particular, if the absorber layer 10 comprises or consists of a phase change material, the phase change material can be brought into the amorphous or crystalline phase via the application of a voltage. Thus, the absorption coefficient of the absorber 6 can be adjusted.

The absorption coefficient of a phase change material can be adjusted as follows:

First, the phase change material is heated to a temperature above the glass transition temperature in both the first and second regions. For example, the luminous intensity of the primary radiation can be used to heat the phase change material. For this purpose, all emitters are operated with such a high luminous intensity that the temperature of the absorber exceeds the glass transition temperature. In particular, this luminous intensity is higher than the luminous intensity during operation of the component, for example, higher than the luminous intensity emitted by the emitters in the first operating state. Alternatively, heating of the phase change material can be accomplished by applying a voltage to the absorber layer. In this example, the heating can take place in the nanosecond range. Heating to a temperature above the glass transition temperature causes the phase change material to transition to a melt.

Cooling of the phase change material from the melt can then be initiated by reducing the luminous intensity or turning off the voltage. For example, the emitters associated with the first regions are turned off or operated with low luminous intensity to achieve rapid cooling where the phase change material transitions to the amorphous phase. The transition to the amorphous phase can occur via cooling in the nanosecond range (t₁). The emitters associated with the second regions are operated, for example, with a higher luminous intensity to achieve slow cooling during which crystallization nuclei can form and a transition of the phase change material to the crystalline phase occurs. The transition to the crystalline phase can take place via cooling in the microsecond range (t₂).

It is also possible to control the phase transition by a combination of luminous intensity and current feed. For example, exceeding the glass transition temperature occurs electrically and the transition to the crystalline or amorphous phase occurs via luminous intensity, i.e., optically.

Alternatively, the absorption coefficient of a phase change material can also be adjusted as follows:

First, the phase change material is selectively heated on a specific emitter to a temperature above the crystallization temperature. For this purpose, the luminous intensity of the primary radiation is used, for example. Then, the phase change material is cooled down by switching off the emitter or operating it with lower luminous intensity. Depending on how the emitter is operated, rapid cooling occurs, during which the phase change material changes to the amorphous phase, or slow cooling, during which crystallization nuclei can form and a transition of the phase change material to the crystalline phase occurs. For example, rapid cooling occurs by turning off the emitter and slow cooling occurs by operating the emitter with a lower luminous intensity. Thus, the absorption coefficient of the absorber can be selectively adjusted on a specific emitter.

For example, before heating, the absorption coefficient of the absorber on the specific emitter corresponds to the absorption coefficient of the absorber in the second regions. Then, after heating and cooling, the absorption coefficient may correspond to the absorption coefficient of the absorber in the first regions. Alternatively, before heating, the absorption coefficient of the absorber on the specific emitter may correspond to the absorption coefficient of the absorber in the first regions, and then after heating and cooling, the absorption coefficient may correspond to the absorption coefficient of the absorber in the second regions. In particular, the absorption coefficient of a specific emitter can be selectively adjusted when the assignment of an emitter to the first or second operating condition changes without changing the absorption coefficients of the absorbers on the other emitters.

FIG. 8 shows a rough estimate of the relative contrast K in % plotted against the relative brightness loss V in %. It can be seen that a contrast improvement is always accompanied by a loss of component brightness. With a brightness loss of 25%, a contrast improvement of 50% is achieved. Thus, the contrast of the electronic component can be improved at the cost of component brightness.

The features and examples described in connection with the figures may be combined in accordance with further examples, although not all combinations are explicitly described. Furthermore, the examples described in connection with the figures may alternatively or additionally comprise further features according to the description in the general part.

This disclosure is not limited to the examples by the description based thereon. Rather, the disclosure encompasses any new feature as well as any combination of features, which in particular includes any combination of features in the appended claims, even if the feature or combination itself is not explicitly specified in the claims or examples.

This application claims priority to German patent application DE 10 2020 104 670.7, the subject matter of which is hereby incorporated by reference.

1.-16. (canceled)

17. An optoelectronic component comprising:
a semiconductor chip with a plurality of emitters configured independently of one another to emit a primary radiation in a main radiation direction in a first operating state and not to emit primary radiation in a second operating state, and
an absorber arranged subsequent to the emitters in the main radiation direction,
wherein
the absorber comprises a lower absorption coefficient in first regions associated with emitters in the first operating state than in second regions associated with emitters in the second operating state,
a conversion layer is arranged in the main radiation direction on at least one emitter of the semiconductor chip, and
1) the absorber is present in particle form embedded in the conversion layer, or
2) the absorber is present in an absorber layer, wherein the absorber layer is arranged in the main radiation direction on a side of the conversion layer facing away from the semiconductor chip, and the absorber layer is electrically contacted.

18. The optoelectronic component according to claim 17, wherein the absorber is a saturable absorber.

19. The optoelectronic component according to claim 17, wherein an absorption coefficient of the saturable absorber decreases with increasing intensity of an electromagnetic radiation.

20. The optoelectronic component according to claim 18, wherein the saturable absorber is selected from the group consisting of graphene, GeSbTe, GaN, InGaN and combinations thereof.

21. The optoelectronic component according to claim 17, wherein the absorber is a phase change material.

22. The optoelectronic component according to claim 17, wherein the phase change material comprises a reversible phase transition from a crystalline phase to an amorphous phase.

23. The optoelectronic component according to claim 22, wherein the phase transition is thermally controlled.

24. The optoelectronic component according to claim 22, wherein the crystalline phase comprises a higher absorption coefficient than the amorphous phase.

25. The optoelectronic component according to claim 24, wherein an absorption coefficient of the crystalline phase is higher by a factor of two than an absorption coefficient of the amorphous phase.

26. The optoelectronic component according to claim 22, wherein the phase change material is selected from the group consisting of GeTe, GeSbTe, Ge₂Sb₂Te₅, GeSb₂Te₄, GeSb₄Te₇, Sb₂Te₃, VO₂, V₂O₅, AgInTe₂, InSb and combinations thereof.

27. The optoelectronic component according to claim 17, wherein a concentration of the absorber in the conversion layer is 0 wt % to 15 wt %.

28. A method of contrast enhancement between emitters of an optoelectronic component, wherein the optoelectronic component comprises a semiconductor chip with a plurality of emitters independently of one another configured to emit a primary radiation in a main radiation direction in a first operating state and not to emit primary radiation in a second operating state, and an absorber arranged subsequent to the emitters in the main radiation direction, wherein
the absorber comprises a lower absorption coefficient in first regions associated with emitters in the first operating state than in second regions associated with emitters in the second operating state,
the method comprising:
heating the absorber to a temperature above the glass transition temperature,
cooling the absorber in the first regions to a temperature below the glass transition temperature in a time t₁, and
cooling the absorber in the second regions to a temperature below the glass transition temperature in a time t₂,
wherein t₁<t₂.

29. The method according to claim 28, wherein the absorber is a phase change material.

30. The method according to claim 28, wherein heating the absorber to a temperature above the glass transition temperature is performed electrically or optically.

31. A method of varying a contrast between emitters of an optoelectronic component, wherein the optoelectronic component comprises a semiconductor chip with a plurality of emitters independently of one another configured to emit a primary radiation in a main radiation direction in a first operating state and not to emit primary radiation in a second operating state, and an absorber arranged subsequent to the emitters in the main radiation direction, wherein
the absorber comprises a lower absorption coefficient in first regions associated with emitters in the first operating state than in second regions associated with emitters in the second operating state,
the method comprising:
heating the absorber on at least one emitter to a temperature above the crystallization temperature, and
cooling the absorber on the at least one emitter to a temperature below the crystallization temperature, wherein the absorption coefficient of the absorber on the at least one emitter after cooling is changed with respect to the absorption coefficient before heating.
